(19) United States
(12) Patent Application Publication
(10) Pub. No.: US 2005/0130069 A1
(43) Pub. Date: Jun. 16, 2005

(54) Resist pattern forming method

(75) Inventor: Masaharu Takizawa, Tokyo (JP)

Correspondence Address: Paul J. Esatto, Jr.;Scully, Scott, Murphy & Presser, 400 Garden City Plaza, Garden City, NY, 11530, US

(73) Assignee: Elpida Memory, Inc., Tokyo (JP)

(21) Appl. No.: 11/007,881

(22) Filed: Dec. 9, 2004

(30) Foreign Application Priority Data
Dec. 12, 2003 (JP) 2003-414920

(51) Int. Cl. G03F 7/00

(52) U.S. Cl. 430/312; 430/313; 430/326

(57) ABSTRACT

Provided is a resist pattern forming method with a bi-layer resist process, which requires only a simple developing step equivalent to that of a single-layer resist process. The resist pattern forming method comprises the steps of: forming a lower-layer resist film on a substrate; forming a diffusion preventive film on the lower-layer resist film; forming an upper-layer resist film on the diffusion preventive film; exposing the lower-layer resist film and the upper-layer resist film simultaneously; and developing the lower-layer resist film and the upper-layer resist film simultaneously. Si as an etching resistance improving component is contained in the upper-layer resist film but not in the lower-layer resist film. The diffusion preventive film prevents diffusion of Si from the upper-layer resist film to the lower-layer resist film and transmits the light at the time of exposure, while having a characteristic of being eliminated by the developer solution at the time of developing.

### BACKGROUND OF THE INVENTION

1. Field of the Invention

The present invention relates to a resist pattern used for micro-processing in a semiconductor manufacturing technique, etc., and more specifically, to a method for-forming the same.

2. Description of the Related Art

FIG. 1 is a schematic cross section showing a first conventional example of a resist pattern forming method, and the steps are carried out from FIG. 1[1] to FIG. 1[3]. Description will be provided-hereinafter by referring to the drawings.

The first conventional example is a single-layer resist process which is the most popularly used process. First, as shown in FIG. 1[1], an ordinal positive photoresist is applied onto a substrate 50 with an oxide film to form a resist film 51 with a film thickness of about 1 μm. Then, as shown in FIG. 1[2], prepared is a photomask 62 in which a light-shielding film 61 in a prescribed pattern is formed on a transparent substrate 60. KrF laser light 63 is irradiated onto the resist film 51 through the photomask 62 for forming a photosensitive part 52. At last, as shown in FIG. 1[3]; the photosensitive part 52 is removed through performing developing processing by an alkali developer solution for obtaining a resist pattern 53.

However, in the positive photoresist used herein, a component such as Si for improving the resistance characteristic of the resist pattern 53 to dry etching cannot be contained. The reason is that Si is originally an impurity component which gives a bad influence on the resolution of the photoresist so that it is impossible to obtain a sufficient resolution performance with the film thickness (1 μm in this case) of the applied base oxide film, which is sufficient to be resistant to dry etching. In general, it is considered the practical film thickness of the Si-containing photoresist film which can obtain a sufficient resolution property is 200 nm or less. Thus, in the single-layer resist process, it has not been possible to obtain a resist pattern which comprises both the sufficient film thickness and the sufficient resistance to dry etching.

In the drawings, for conveniences' sake, only a part of the substrate 50 is illustrated and the thicknesses of the substrate 50 and the transparent substrate 60 are thinned. It is also the same in other drawings.

Also, there is a bi-layer resist process (for example, Japanese Patent Unexamined Publication No. 3-283418) in which the resist film is not single-layered but bi-layered. The bi-layer resist process in which a Si-containing photoresist is used as an upper-layer resist film will be described next as a second conventional example.

FIG. 2 is a schematic cross section showing the second conventional example of a resist pattern forming method, and the steps are carried out from FIG. 2[1] to FIG. 2[4]. Description will be provided hereinafter by referring to the drawings.

First, as shown in FIG. 2[1], through applying a non-photosensitive resist and a Si-containing positive photoresist in order on a substrate 70 with an oxide film, a non-photosensitive lower-layer resist film 71 (film thickness of about 800 nm) and a Si-containing upper-layer resist film 72 (film thickness of about 200 nm) are formed. As the non-photosensitive resist, mainly used are novolak-based resin and acrylic-based resin, which do not contain a photosensitive component such as a photo-acid generator. Further, as the positive photoresist, mainly used are the Si-containing photoresist having polysiloxane-based resin or polyhydroxystyrene resin as a base.

Subsequently, as shown in FIG. 2[2], prepared is a photomask 82 in which a light-shielding film 81 in a prescribed pattern is formed on a transparent substrate 80. KrF laser light 83 is irradiated onto the upper-layer resist film 72 through the photomask 82 for forming a photosensitive part 73 on the upper-layer resist film 72.

Then, as shown in FIG. 2[3], through dissolving the photosensitive part 73 in an alkali developer solution, a resist pattern 74 comprising only the upper-layer resist 72 is obtained. The lower-layer resist 71 at this time is non-photosensitive so that it is not patterned by the alkali developer solution.

At last, as shown in FIG. 2[4], through performing a dry-developing processing using a mixed gas of SO₂+O₂ with the resist pattern 74 being a mask, a complete resist pattern 75 comprising the lower-layer resist film 71 and the upper-layer resist film 72 is obtained.

With the bi-layer resist process, it is possible to obtain the resist pattern 75 having a sufficient resistant to etching without deteriorating the resolution.

As described, with the bi-layer resist process which uses the Si-containing photoresist as the upper-layer resist film 72, it is possible to obtain the resist pattern 75 having a high resistance to dry etching, which cannot be achieved by the single-layer process used in an ordinal semiconductor manufacturing steps. Therefore, it is considered to be very effective to be applied to the steps for processing a thick base film, such as when etching a dielectric film.

However, there is such a shortcoming in the conventional bi-layer resist process that the numbers of the steps and the devices to be used are increased, since it requires a dry-developing processing performed on the lower-layer resist film 71, totaling two developing steps together with the developing processing of the upper-layer resist film 72 using the alkali developer solution.

An object of the present invention therefore is to provide a resist pattern forming method with a bi-layer resist process, which only requires a simple developing step equivalent to that of a single-layer resist process.

### SUMMARY OF THE INVENTION

The resist pattern forming method according to the present invention comprises steps of: forming a positive lower-layer resist film on a substrate which is a subject of etching; forming a positive upper-layer resist film on the lower-layer resist film; exposing the lower-layer resist film and the upper-layer resist film simultaneously; and developing the lower-layer resist film and the upper-layer resist film simultaneously. An etching resistance improving component for improving resistance to the etching is contained only in the upper-layer resist film.

First, on the substrate, the lower-layer resist film and the upper-layer resist film are formed in order. The lower-layer resist film and the upper-layer resist film are both the same positive type so that the both can be exposed simultaneously and also developed simultaneously. Thus, although it is a bi-layer resist process, it only requires a single developing step, which is the same as the case of a single-layer resist process. Further, the lower-layer resist film does not contain an etching resistance improving component so that it exhibits a good light-transmittance. On the other hand, the upper-layer resist film which is exposed to a substrate etchant contains the etching resistance improving component. Therefore, it enables to obtain a resist pattern having a sufficient etching resistance without deteriorating the resolution.

The resist pattern forming method according to the present invention further comprises a step of forming a diffusion preventive film between the lower-layer resist film and the upper-layer resist film. The diffusion preventive film prevents diffusion of the etching resistance improving component from the upper-layer resist film to the lower-layer resist film and transmits light at the time of the exposure, while having a characteristic of being eliminated by a developer solution at the time of the developing.

When the etching resistance improving component is diffused from the upper-layer resist film to the lower-layer resist film, the light-transmittance of the lower-layer resist film is deteriorated. Thus, the diffusion preventive film is provided as described above when the diffusion of the etching resistance improving component is an issue. The diffusion preventive film also transmits the light of the exposure and is eliminated by the developer solution at the time of developing. Therefore, there is no increase in the number of the exposing step and the developing step even if there is the diffusion preventive film being provided.

Further, in the resist pattern forming method according to the present invention, the lower-layer resist film is formed by photoresist which is more sensitive to the light of the exposure compared to the upper-layer resist film.

The light of the exposure transmits through the upper-layer resist film and reaches the lower-layer resist film so that it is slightly attenuated when reaching the lower-layer resist film. Especially, there is an etching resistance improving component contained in the upper-layer resist film so that the attenuation amount of the light is large. Therefore, the lower-layer resist film is set to have higher sensitivity than that of the upper-layer resist film so that the lower-layer resist film and the upper-layer resist film are uniformly exposed.

Further, in the resist pattern forming method according to the present invention, a polysiloxane-based resin or a polyhydroxystyrene based resin is used as a resin composing the lower-layer resist film and the upper-layer resist film, and silicon is used as the etching resistance improving component.

Described above are the specific examples of the lower-layer resist film and the upper-layer resist film, and that of the etching resistance improving component. Needless to say, the lower-layer resist film, the upper-layer resist film, and the etching resistance improving component are not limited to the specific examples.

Furthermore, in the resist pattern forming method according to the present invention, an alkali developer solution is used as the developer solution and the diffusion preventive film is made of a copolymer containing polyvinyl alcohol or polyvinyl pyrrolidone as a base, which is soluble to the alkali developer solution.

Described above are the specific examples of the developer solution and the diffusion preventive film. However, the developer solution and the diffusion preventive film are not limited to the specific examples.

A dissolution velocity of the diffusion preventive film with respect to the alkali developer solution is set by adjusting a copolymerization ratio of a soluble component to an insoluble component in a monomer used as a raw material of the diffusion preventive film.

The dissolution velocity of the diffusion preventive film with respect to the alkali developer solution is increased with a larger amount of the soluble component in the diffusion preventive film.

A negative lower-layer resist film and a negative upper-layer resist film may be used instead of the positive lower-layer resist film and the positive upper-layer resist film.

In general, the resolution of the negative type is lower than that of the positive type. The reason is that the negative becomes swollen by absorbing the developer solution at the time of the developing processing. Thus, the negative type may be used if the low resolution is not an issue.

Further, the resist pattern forming method according to the present invention comprises steps of: forming a lower-layer resist film having a high-sensitive optical property on a substrate; forming a diffusion preventive film having a non-photosensitivity on the lower-layer resist film; forming an upper-layer resist film having a low-sensitive optical property on the diffusion preventive film; exposing the formed films by irradiating exposure light; and developing the films to which the exposure is performed. In this case, a film thickness of the diffusion preventive film is set thinner than film thicknesses of the other resist films. Also, the lower-layer resist film and the upper-layer resist film are formed with a positive photoresist.

The present invention is a resist pattern forming method in which a positive lower-layer resist film (high-sensitive), a diffusion preventive film (non-photosensitive), a Si-containing positive upper-layer resist film (low-sensitive) are formed on a substrate in order, and the positive lower-layer resist film and the Si-containing positive upper-layer resist film are exposed and developed simultaneously.

As the lower-layer resist film, a positive photoresist having a photosensitivity is used. The Si-containing positive upper-layer resist film and the positive lower-layer resist film are simultaneously exposed and simultaneously developed by an alkali developer solution. Thus, a dry-developing processing of the lower-layer resist film, which has been conventionally performed, becomes unnecessary. However, in order to prevent the diffusion of Si, it is preferable to provide the diffusion preventive film in between the both resist films. Also, in order to make the sidewalls of the resist pattern perpendicular, it is preferable to set the sensitivity of the positive lower-layer resist film higher than that of the positive upper-layer resist film.

As described above, in a bi-layer resist process which uses the Si-containing photoresist as the upper-layer resist film, it is possible to omit the dry-developing processing for developing the lower-layer resist film. Therefore, the resist pattern having a high dry-etching resistance can be easily formed.

In the resist pattern forming method according to the present invention, provided are two layers comprising the positive lower-layer resist film which does not contain the etching resistance improving component and the positive upper-layer resist film which contains the etching resistance improving component, so that the films can be exposed simultaneously and also developed simultaneously. Thus, although it is the bi-layer resist process, it only requires a single developing step which is equivalent to that of the single-layer resist process. Moreover, the lower-layer resist film does not contain the etching resistance improving component so that it has a good light-transmittance, while the upper-layer resist film which is exposed to an etchant contains the etching resistance improving component. Therefore, it is possible to obtain a resist pattern with a sufficient etching resistance by a simple manufacturing process without deteriorating the resolution. Further, the present invention achieves the following effects according to each aspect.

In the resist pattern forming method according to an aspect of the present invention, the diffusion preventive film is formed between the lower-layer resist film and the upper-layer resist film. Thus, the light-transmittance of the lower-layer resist film is not deteriorated by diffusion of the etching resistance improving component from the upper-layer resist film. Furthermore, the diffusion preventive film transmits the light of the exposure and is eliminated by the developer solution at the time of developing. Therefore, the resolution can be improved without increasing the number of the exposure step and the developing step.

In the resist pattern forming method according to another aspect of the present invention, the lower-layer resist film provided under the upper-layer resist film containing the etching resistance improving component for blocking the transmittance of light is formed to have higher sensitivity than that of the upper-layer resist film. Thus, the lower-layer resist film is exposed together with the upper-layer resist film in the same manner so that the lower-layer resist film and the upper-layer resist film can be uniformly exposed. Therefore, the sidewalls of the lower-layer resist film after the developing can be formed perpendicular so that the etching precision of the substrate can be improved.

### BRIEF DESCRIPTION OF THE DRAWINGS

FIG. 1 is a schematic cross section showing the steps of a conventional resist pattern forming method in order;

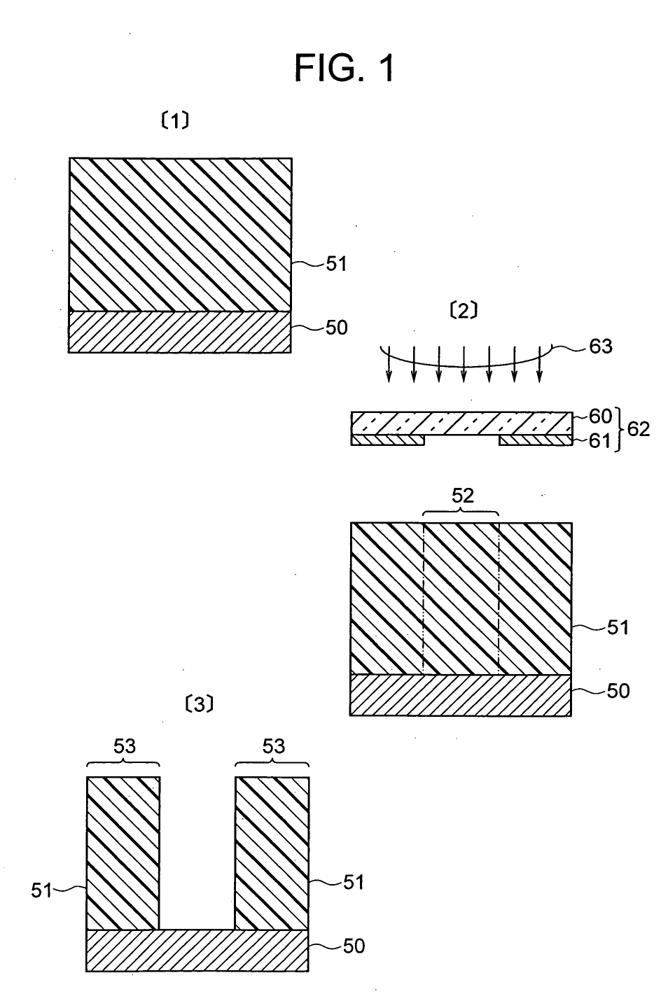

FIG. 2 is a schematic cross section showing the steps of another conventional resist pattern forming method in order;

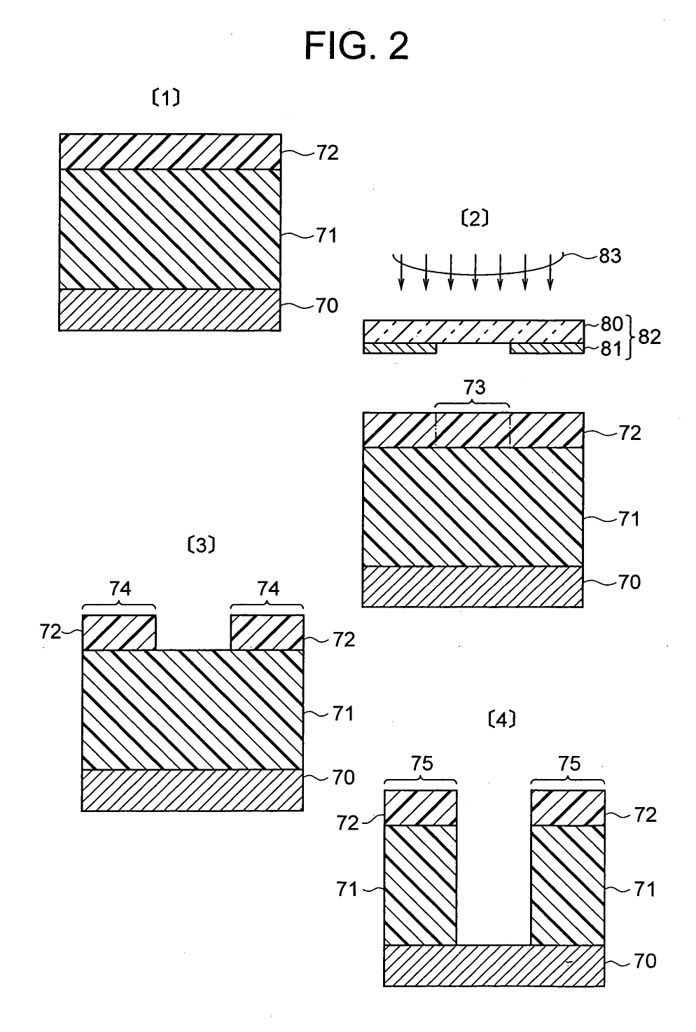

FIG. 3 is a flowchart showing a resist pattern forming method according to the present invention; and

FIG. 4 is a schematic cross section showing an embodiment of the resist pattern forming method according to the present invention shown in FIG. 3 in the order of the steps.

### DESCRIPTION OF THE PREFERRED EMBODIMENTS

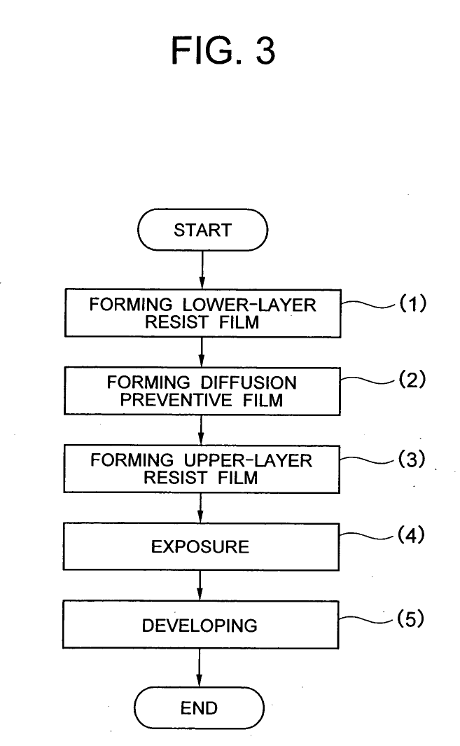

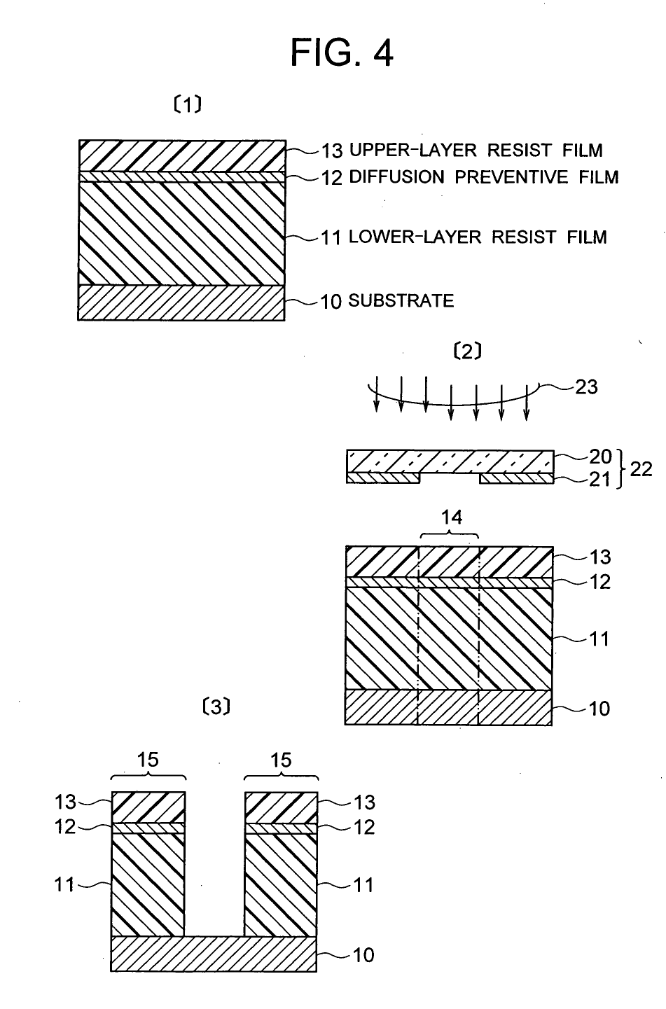

FIG. 3 is an illustration for describing the steps of an embodiment of the resist pattern forming method according to the present invention. FIG. 4 is a schematic cross section of the embodiment, in which the steps are carried out in order from FIG. 4[1] to FIG. 4.[3].

In the followings, description will be provided by referring to the drawings.

The outline of the embodiment will be described by referring to FIG. 3 and FIG. 4[1].

The resist pattern forming method according to the embodiment comprises the steps of: forming a positive lower-layer resist film 11 on a substrate 10 as a subject of etching (1); forming a diffusion preventive film 12 on the lower-layer resist film 11 (2); forming a positive upper-layer resist film 13 on the diffusion preventive film 12 (3); exposing the lower-layer resist film 11 and the upper-layer resist film 13 simultaneously (4); and developing the lower-layer resist film 11 and the upper-layer resist film 13 simultaneously (5).

Si as an etching resistance improving component for improving the resistance to etching is contained in the upper-layer resist film 13 but not in the lower-layer resist film 11. The diffusion preventive film 12 prevents the diffusion of Si from the upper-layer resist film 13 to the lower-layer resist film 11 and transmits the light of the exposure, while having a characteristic of being eliminated by the developer solution at the time of developing.

Next, it will be described in more detail by referring to FIG. 4[1] to FIG. 4[3].

First, as shown in FIG. 4 [1], the lower-layer resist film 11, the diffusion preventive film 12 and the upper-layer resist film 13 are formed by applying a positive photoresist for the lower layer, a resin for the diffusion preventive film, and a positive photoresist for the upper layer in order on a substrate 10 with an oxide film. For the lower-layer resist film 11, for example, used is a chemical-amplified photoresist of about 800 nm in film thickness for KrF excimer laser. The chemically-amplified photoresist is made of a mixed solution of a resin, acid generator, solvent and the like. The chemically-amplified photoresist used herein may be the most popular one which uses polyhydroxystyrene as a base. For the upper-layer resist film 13, for example, used is a KrF-photosensitive Si-containing photoresist of about 200 nm in film thickness. This also may be the most popular Si-containing photoresist which uses a polysiloxane-based resin or polyhydroxystyrene resin as a base. Further, between the lower-layer resist film 11 and the upper-layer resist film 13, the non-photosensitive diffusion preventive film 12 of about some nm to some ten nm in film thickness having a characteristic of transmitting the KrF light is formed by application. The diffusion preventive film 12 prevents the deterioration of the resolution performance due to a mutual diffusion of the both resist films 11 and 13 during pre-baking which is performed after the application of the resist and before the developing.

Then, as shown in FIG. 4[2], provided is a photomask 22 in which a light-shielding film 21 in a prescribed pattern is formed on a transparent substrate 20. A photosensitive part 14 is simultaneously formed on the lower-layer resist film 11 and the upper-layer resist film 13 by performing the exposure using the photomask 22 and a KrF laser light 23.

Subsequently, as shown in FIG. 4[3], a resist pattern 15 is obtained by dissolving the photosensitive part 14 formed by the lower-layer resist film 11 and the upper-layer resist film 13 using the alkali developer solution. The diffusion preventive film 12 is not photosensitive. At this time, although the diffusion preventive film 12 is not photosensitive, since its film thickness is thin, it is dissolved in the alkali developer solution along with the lower-layer resist film 11 and the upper-layer resist film 13 and patterned. Examples of a material used for the diffusion preventive film 12 which is soluble to the alkali developer solution may be a copolymer containing polyvinyl alcohol or polyvinyl pyrrolidone as a base. An appropriate dissolution velocity of the diffusion preventive film 12 with respect to the alkali developer solution may be about 8×10⁻⁵ μm/s to 8×10⁻⁴ μm/s. The dissolution velocity can be controlled by adjusting the polymerization ratio of the soluble component to insoluble component in a raw material (monomer). In order to make the sidewall of the resist pattern 15 perpendicular, it is necessary to set the photosensitivity of the lower-layer resist film 11 to the KrF light higher than that of the upper-layer resist film 13.

When dry etching is performed on the substrate 10 with the oxide film using the resist pattern 15 obtained by the method described above, it enables to sufficiently obtain a selection ratio of an etching rate since there is the Si-containing layer with an excellent dry-etching resistance provided on the upper layer of the resist pattern 15. Further, the lower-layer resist film 11 and the upper-layer resist film 13 are simultaneously patterned by the alkali developer solution so that it is possible to omit the dry-developing processing which is performed in a conventional bi-layer resist process for developing the lower-layer resist film.

Needless to say, the present invention is not limited to the above-described embodiment. For example, although the above-described embodiment illustrates a combination of the KrF-photosensitive positive photoresist along with the upper-layer resist film and the lower-layer resist film, it is possible to achieve the similar effect by a combination of positive photoresist which is photosensitive to a laser light other than the KrF (krypton fluoride) excimer laser light source (248 nm), such as ArF (argon fluoride) excimer laser light source (193 nm) or F2 (fluorine dimer) excimer laser light source (157 nm). Further, the diffusion preventive film may be omitted if it tolerates the diffusion of Si.

1. A resist pattern forming method, comprising steps of:
forming a positive lower-layer resist film on a substrate which is a subject of etching;
forming a positive upper-layer resist film on the lower-layer resist film;
exposing the lower-layer resist film and the upper-layer resist film simultaneously; and
developing the lower-layer resist film and the upper-layer resist film simultaneously, wherein
an etching resistance improving component for improving resistance to the etching is contained only in the upper-layer resist film.

2. The resist pattern forming method according to claim 1, further comprising a step of forming a diffusion preventive film between the lower-layer resist film and the upper-layer resist film, wherein
the diffusion preventive film prevents diffusion of the etching resistance improving component from the upper-layer resist film to the lower-layer resist film and transmits light at the time of the exposure, while having a characteristic of being eliminated by a developer solution at the time of the developing.

3. The resist pattern forming method according to claim 1, wherein the lower-layer resist film is more sensitive to the light of the exposure compared to the upper-layer resist film.

4. The resist pattern forming method according to claim 2, wherein the lower-layer resist film is more sensitive to the light of the exposure compared to the upper-layer resist film.

5. The resist pattern forming method according to any one of claims 1, wherein:
a resin composing the lower-layer resist film and the upper-layer resist film is a polysiloxane-based resin or a polyhydroxystyrene-based resin; and
the etching resistance improving component is silicon.

6. The resist pattern forming method according to any one of claims 1, wherein:
the developer solution is an alkali developer solution; and
the diffusion preventive film is made of a copolymer containing polyvinyl alcohol or polyvinyl pyrrolidone as a base, which is soluble to the alkali developer solution.

7. The resist pattern forming method according to claim 6, wherein a dissolution velocity of the diffusion preventive film with respect to the alkali developer solution is set by adjusting a copolymerization ratio of a soluble component to an insoluble component in a monomer used as a raw material of the diffusion preventive film.

8. The resist pattern forming method according to any one of claims 1, wherein:
a negative lower-layer resist film and a negative upper-layer resist film are provided instead of the positive lower-layer resist film and the positive upper-layer resist film.

9. A resist pattern forming method, comprising steps of:
forming a lower-layer resist film having a high-sensitive optical property on a substrate;
forming a diffusion preventive film having a non-photosensitivity on the lower-layer resist film;
forming an upper-layer resist film having a low-sensitive optical property on the diffusion preventive film;
exposing the formed films by irradiating exposure light; and
developing the films to which the exposure is performed.

10. The resist pattern forming method according to claim 9, wherein a film thickness of the diffusion preventive film is set thinner than film thicknesses of the other resist films.

11. The resist pattern forming method according to claim 9, wherein the lower-layer resist film and the upper-layer resist film are formed with a positive photoresist.
